(19) United States
(12) Patent Application Publication
(10) Pub. No.: US 2026/0121657 A1
(43) Pub. Date: Apr. 30, 2026

(54) INTER-SEGMENT SWAPPING METHOD FOR CONTROLLING OF SEGMENTED DIGITAL-TO-ANALOG CONVERTER

(71) Applicant: Mediatek Inc., Hsinchu City (TW)

(72) Inventors: Min-Jui Chiu, Hsinchu City (TW); Wei-Te Lin, Hsinchu City (TW)

(73) Assignee: Mediatek Inc., Hsinchu City (TW)

(21) Appl. No.: 19/372,318

(22) Filed: Oct. 29, 2025

Related U.S. Application Data
(60) Provisional application No. 63/713,588, filed on Oct. 30, 2024.

(51) Int. Cl. H03M 1/68

(52) U.S. Cl. CPC H03M 1/687

(57) ABSTRACT

An inter-segment swapping (ISS) method for controlling segments of a segmented digital-to-analog converter (DAC) includes receiving a first output code derived from higher significant bits of a digital input code; receiving a second output code derived from lower significant bits of the digital input code; deriving a first pre-ISS control code of a higher-significant-bit segment from the first output code; deriving a second pre-ISS control code of a lower-significant-bit segment from the second output code; and performing an ISS operation upon the first pre-ISS control code and the second pre-ISS control code to generate a first post-ISS control code of the higher-significant-bit segment and a second post-ISS control code of the lower-significant-bit segment, including: swapping a first control bit of a first DAC cell included in the higher-significant-bit segment for second control bits of multiple second DAC cells included in the lower-significant-bit segment.

### CROSS REFERENCE TO RELATED APPLICATIONS

This application claims the benefit of U.S. Provisional Application No. 63/713,588, filed on Oct. 30, 2024. The content of the application is incorporated herein by reference.

### BACKGROUND

The present invention relates to a digital-to-analog conversion technique, and more particularly, to an inter-segment swapping (ISS) method for controlling segments of a segmented digital-to-analog converter (DAC) and an associated segmented DAC with ISS.

The evolution of advanced complementary metal-oxide-semiconductor (CMOS) processes has pushed the boundaries of analog and mixed-signal design towards high-fidelity and high-accuracy implementations while maintaining high-speed operation. Despite digital processing advancements and signal integrity advantages, real world signals are inevitably analog. Thus, high-speed digital-to-analog converters (DACs) are developed to enable the link between analog and digital domains. When it is required to design a DAC with a specific performance, there is no single architecture that is ideal. In such cases, two or more lower-resolution DACs may be combined in a single higher-resolution DAC to give the required performance. For example, a conventional segmented DAC may consist of a most significant bit (MSB) segment, an upper significant bit (USB) segment, and a least significant bit (LSB) segment. Each of the MSB segment, the USB segment, and the LSB segment may be implemented using a current-steering DAC having a plurality of DAC cells, where each DAC cell may include a current source and a switch element. However, each DAC cell may suffer amplitude mismatch and timing mismatch, causing distortion in an output spectrum of the conventional segmented DAC. Specifically, the amplitude mismatch is induced by random mismatch among current sources of different DAC cells, and the timing mismatch is induced by timing-skew among switch elements of different DAC cells. The conventional segmented DAC may employ a dynamic element matching (DEM) technique to randomize selection of DAC cells in the same segment, leading to improved spurious-free dynamic range (SFDR) at the cost of large switching activity and worse signal-to-noise ratio (SNR). In addition, the DEM technique applied to DAC cells in the same segment is unable to suppress distortion induced by timing mismatch between DAC cells of different segments.

Thus, there is a need for an innovative scheme capable of suppressing both amplitude mismatch and timing mismatch in a segmented DAC.

### SUMMARY

One of the objectives of the claimed invention is to provide an inter-segment swapping (ISS) method for controlling segments of a segmented digital-to-analog converter (DAC) and an associated segmented DAC with ISS.

According to a first aspect of the present invention, an exemplary inter-segment swapping (ISS) method for controlling a plurality of segments of a segmented digital-to-analog converter (DAC) is disclosed. The exemplary ISS method includes: receiving a first output code derived from higher significant bits of a digital input code of the segmented DAC; receiving a second output code derived from lower significant bits of the digital input code of the segmented DAC; deriving a first pre-ISS control code of a higher-significant-bit segment included in the plurality of segments of the segmented DAC from the first output code, wherein the first pre-ISS control code comprises first control bits corresponding to first DAC cells of the higher-significant-bit segment, respectively; deriving a second pre-ISS control code of a lower-significant-bit segment included in the plurality of segments of the segmented DAC from the second output code, wherein the second pre-ISS control code comprises second control bits corresponding to second DAC cells of the lower-significant-bit segment, respectively; and performing an ISS operation upon the first pre-ISS control code and the second pre-ISS control code to generate a first post-ISS control code of the higher-significant-bit segment and a second post-ISS control code of the lower-significant-bit segment, comprising: swapping a first control bit of a first DAC cell included in the higher-significant-bit segment for second control bits of multiple second DAC cells included in the lower-significant-bit segment.

According to a second aspect of the present invention, an exemplary inter-segment swapping (ISS) method for controlling a plurality of segments of a segmented digital-to-analog converter (DAC) is disclosed. The exemplary ISS method includes: receiving a first output code derived from higher significant bits of a digital input code of the segmented DAC; receiving one or more second output codes derived from lower significant bits of the digital input code of the segmented DAC; deriving a first pre-ISS control code of a higher-significant-bit segment included in the plurality of segments of the segmented DAC from the first output code, wherein the first pre-ISS control code comprises first control bits corresponding to first DAC cells of the higher-significant-bit segment, respectively; deriving one or more second pre-ISS control codes of one or more lower-significant-bit segments included in the plurality of segments of the segmented DAC from the one or more second output codes, wherein the one or more second pre-ISS control codes comprise second control bits corresponding to second DAC cells of the one or more lower-significant-bit segments, and respectively; performing an ISS operation upon the first pre-ISS control code and the one or more second pre-ISS control codes to generate a first post-ISS control code of the higher-significant-bit segment and one or more second post-ISS control codes of the one or more lower-significant-bit segments, comprising: swapping a first control bit of a first DAC cell included in the higher-significant-bit segment for second control bits of all second DAC cells included in the one or more lower-significant-bit segments, or swapping second control bits of all second DAC cells included in the one or more lower-significant-bit segments for a first control bit of a first DAC cell included in the higher-significant-bit segment.

According to a third aspect of the present invention, an exemplary segmented digital-to-analog converter (DAC) is disclosed. The exemplary segmented DAC includes a plurality of segments, a combining circuit, a segmentation circuit, and an inter-segment swapping (ISS) circuit. The segments include a higher-significant-bit segment comprising first DAC cells and a lower-significant-bit segment comprising second DAC cells. The combining circuit is configured to combine analog outputs of the segments. The segmentation circuit is configured to derive a first output code from higher significant bits of a digital input code of the segmented DAC, and derive a second output code from lower significant bits of the digital input code of the segmented DAC. The ISS circuit is configured to derive a first pre-ISS control code of the higher-significant-bit segment from the first output code, derive a second pre-ISS control code of the lower-significant-bit segment from the second output code, and perform an ISS operation upon the first pre-ISS control code and the second pre-ISS control code to generate a first post-ISS control code of the higher-significant-bit segment and a second post-ISS control code of the lower-significant-bit segment, wherein the first pre-ISS control code comprises first control bits corresponding to the first DAC cells, respectively, the second pre-ISS control code comprises second control bits corresponding to the second DAC cells, respectively, and the ISS operation comprises swapping a first control bit of a first DAC cell included in the higher-significant-bit segment for second control bits of multiple second DAC cells included in the lower-significant-bit segment.

The ISS scheme involves swapping between different segments, and is capable of suppressing distortion induced by timing mismatch between DAC cells of different segments.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a segmented DAC with ISS according to an embodiment of the present invention.

FIG. 2 is a diagram illustrating current ratio settings of DAC cells shown in FIG. 1.

FIG. 3 a diagram illustrating an ISS operation performed at an ISS circuit shown in FIG. 1 according to an embodiment of the present invention.

FIG. 4 is a diagram illustrating a comparison between the conventional DEM technique and the proposed ISS scheme.

FIG. 5 is a diagram illustrating an ISS operation without checking a previous state according to an embodiment of the present invention.

FIG. 6 is a diagram illustrating another ISS operation without checking a previous state according to an embodiment of the present invention.

FIG. 7 is a diagram illustrating an ISS operation controlled by a fixed sequence carried by an ISS index control signal according to an embodiment of the present invention.

FIG. 8 is a diagram illustrating an ISS operation controlled by a random sequence carried by an ISS index control signal according to an embodiment of the present invention.

FIG. 9 is a diagram illustrating an ISS operation with USB DEM according to an embodiment of the present invention.

FIG. 10 is a diagram illustrating another segmented DAC with ISS according to an embodiment of the present invention.

FIG. 11 is a diagram illustrating current ratio settings of DAC cells shown in FIG. 10.

FIG. 12 is a diagram illustrating an ISS operation performed at an ISS circuit shown in FIG. 10 according to an embodiment of the present invention.

FIG. 13 is a diagram illustrating another ISS operation performed at an ISS circuit shown in FIG. 10 according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

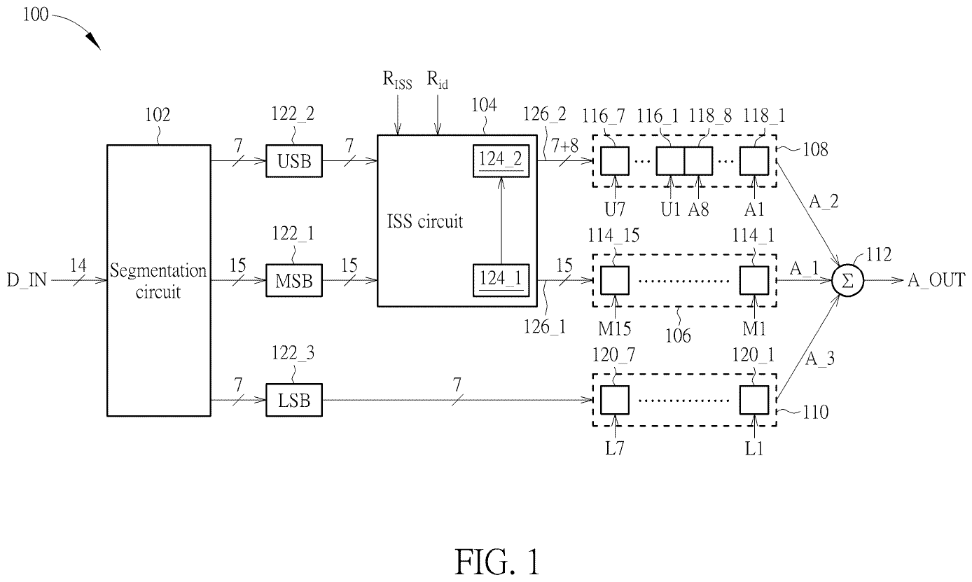

FIG. 1 is a diagram illustrating a segmented DAC with inter-segment swapping (ISS) according to an embodiment of the present invention. The segmented DAC 100 includes a segmentation circuit 102, an ISS circuit 104, a plurality of segments 106, 108, 110, and a combining circuit 112. In this embodiment, the segmented DAC 100 is designed to receive a 14-bit digital input code D_IN, and perform digital-to-analog conversion upon the 14-bit digital input code D_IN to generate an analog output A_OUT. In a case where the segmented DAC 100 is a current-steering DAC, the analog output A_OUT may be an analog current output. For example, the analog current output may be a differential pair consisting of I_{OUT}+ and I_{OUT}−.

The segmentation circuit 102 is configured to derive a plurality of output codes 122_1, 122_2, 122_3 from segmentation of the 14-bit digital input code D_IN. For example, the 14-bit digital input code D_IN may be divided into 4 most significant bits (MSBs), 3 upper significant bits (USBs), and 7 least significant bits (LSBs). In this embodiment, the segmentation circuit 102 may include a binary-to-thermometer decoder for translating 4 MSBs into a 15-bit output code (labeled by “MSB”) 122_1 and translating 3 USBs into a 7-bit output code (labeled by “USB”) 122_2. In addition, the segmentation circuit 102 may generate a 7-bit output code (labeled by “LSB”) 122_3 by simply passing 7 LSBs through a delay circuit (not shown). In other words, bits of the 7-bit output code 122_3 are the same as LSBs.

The segment 106 is an MSB segment including DAC cells (i.e., MSB cells) 114_1-114_15. The segment 108 is a USB segment including DAC cells (i.e., USB cells) 116_1-116_7 and 118_1-118_8. In this embodiment, the DAC cells 118_1-118_8 are M (M=8) redundant USB cells required by the proposed ISS scheme, where M can be adjusted depending upon actual design consideration. Specifically, these redundant cells of a lower-significant-bit segment (e.g., USB segment 108) are used to enable a change of a DAC cell connection state of a DAC cell included in a higher-significant-bit segment (e.g., MSB segment 106) replaced by changes of DAC cell connection states of multiple DAC cells included in the lower-significant-bit segment (e.g., USB segment 108), where a DAC cell has one DAC cell connection state “1” when a current source is connected to an I_{OUT}+ node through a switch element, and has another DAC cell connection state “−1” when the current source is connected to an I_{OUT}− node through the switch element. The segment 110 is an LSB segment including DAC cells (i.e., LSB cells) 120_1-120_7.

The ISS circuit 104 is configured to derive a 15-bit pre-ISS control code 124_1 of the MSB segment 106 from the 15-bit output code 122_1, and is further configured to derive a 15-bit pre-ISS control code 124_2 of the USB segment 108 from the 7-bit output code 122_2. Specifically, the 15-bit pre-ISS control code 124_2 includes a first code segment and a second code segment, where the first code segment is directly set by the 7-bit output code 122_2 (which includes 7 bits corresponding to the USB cells 116_1-116_7, respectively), and the second code segment includes 8 bits corresponding to the redundant USB cells 118_1-118_7, respectively. During each cycle of a DAC clock, the second code segment of the pre-ISS control code 124_2 may be initialized to have 4 bits each set to a same value that corresponds to one DAC cell connection state (e.g., “1”) and 4 bits each set to a same value that corresponds to another DAC cell connection state (e.g., “−1”).

The pre-ISS control code 124_1 includes 15 control bits {M1, . . . , M15} corresponding to MSB cells 114_1-114_15 of the MSB segment 106, respectively. The pre-ISS control code 124_2 includes 15 control bits {U1, . . . , U7, A1, . . . , A8} corresponding to USB cells 116_1-116_7, 118_1-118_8 of the USB segment 108, respectively. The ISS circuit 104 is further configured to perform an ISS operation upon the pre-ISS control codes 124_1 and 124_2 to generate a post-ISS control code 126_1 of the MSB segment 106 and a post-ISS control code 126_2 of the USB segment 108. The post-ISS control code 126_1 includes 15 control bits {M1, . . . , M15} corresponding to MSB cells 114_1-114_15 of the MSB segment 106, respectively, and has one control bit with a value different from a value of the same control bit included in the pre-ISS control code 124_1 due to the ISS operation. The post-ISS control code 126_2 includes 15 control bits {U1, . . . , U7, A1, . . . , A8} corresponding to USB cells 116_1-116_7, 118_1-118_8 of the USB segment 108, respectively, and has multiple control bit with values different from values of the same control bits included in the pre-ISS control code 124_2 due to the ISS operation.

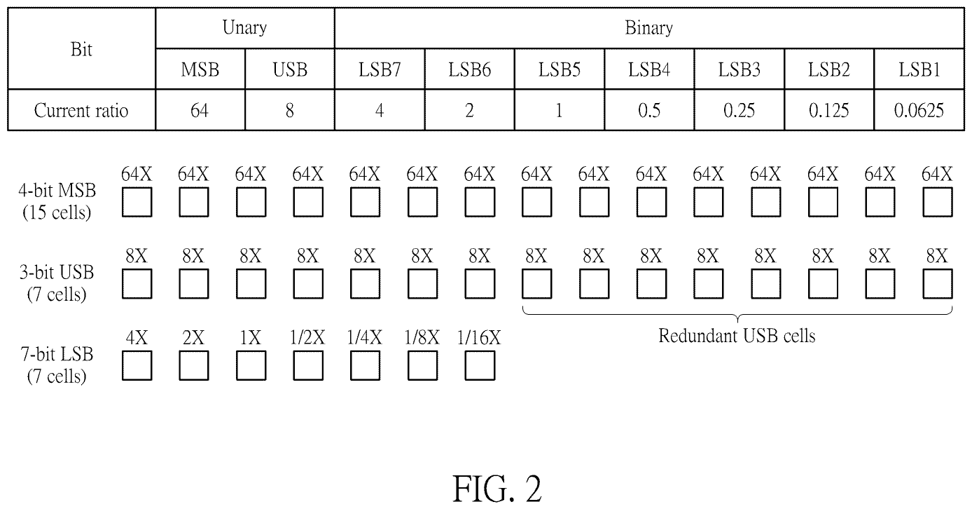

For better comprehension of technical features of the proposed ISS scheme, the following assumes that each of the MSB segment 106, the USB segment 108, and the LSB segment 110 may be a current-steering DAC. Each of the DAC cells 114_1-114_15, 116_1-116_7, 118_1-118_8, 120_1-120_7 may include a current source and a switch element, where the switch element is controlled by a control bit to steer a current of the current source to an I_{OUT}+ node or an I_{OUT}− node. FIG. 2 is a diagram illustrating current ratio settings of the DAC cells 114_1-114_15, 116_1-116_7, 118_1-118_8, 120_1-120_7 shown in FIG. 1. Regarding the MSB segment 106, the MSB cells 114_1-114_15 are unary-weighted DAC cells each having a current ratio of 64X. Regarding the USB segment 108, the USB cells 116_1-116_7, 118_1-118_8 are unary-weighted DAC cells each having a current ratio of 8X. Specifically, the USB cells (e.g., LSB1-LSB7) 116_1-116_7 and the redundant USB cells 118_1-118_8 may be implemented using DAC cells of a same structure. In this way, there is no need to do extra circuit design for redundant USB cells. Additionally, any architecture of current-steering cells for a current-steering DAC can be used as redundant USB cells. Regarding the LSB segment 110, the LSB cells 120_1-120_7 are binary-weighted DAC cells having current ratios of (1/16)X, (1/8)X, (1/4)X, (1/2)X, 1X, 2X, 4X, respectively. Here, the “1X” current indicates the current is derived from a single current source unit, whereas the “(1/16)X”/“(1/8)X”/“(1/4)X”/“(1/2)X” current represents a sub-current generated through current division. Meanwhile, the current source unit is positioned at the LSB5 weighting, rather than at LSB1, to minimize routing parasitics arising from duplication of identical current sources. It should be noted that the current source unit may be placed at any LSB or USB weightings, as this does not disrupt the relative current ratio of the segmented DAC.

When a control bit is set by a first value, a switch element is controlled to steer the current of a current source to the I_{OUT}+ node, resulting in one DAC cell connection state “1”; and when the control bit is set by a second value, the switch element is controlled to steer the current of the current source to the I_{OUT}− node, resulting in another DAC cell connection state “−1”. The combining circuit 112 is configured to combine an analog output A_1 (e.g., analog current outputs I_{OUT}+, I_{OUT}−) of the MSB segment 106, an analog output A_2 (e.g., analog current outputs I_{OUT}+, I_{OUT}−) of the USB segment 108, and an analog output A_3 (e.g., analog current outputs I_{OUT}+, I_{OUT}−) of the LSB segment 110 to generate the analog output A_OUT (e.g., analog current outputs I_{OUT}+, I_{OUT}−) of the segmented DAC 100.

Since the present invention is focused on the ISS operation performed at the ISS circuit 104, further description of other circuit components of the segmented DAC 100 is omitted here for brevity.

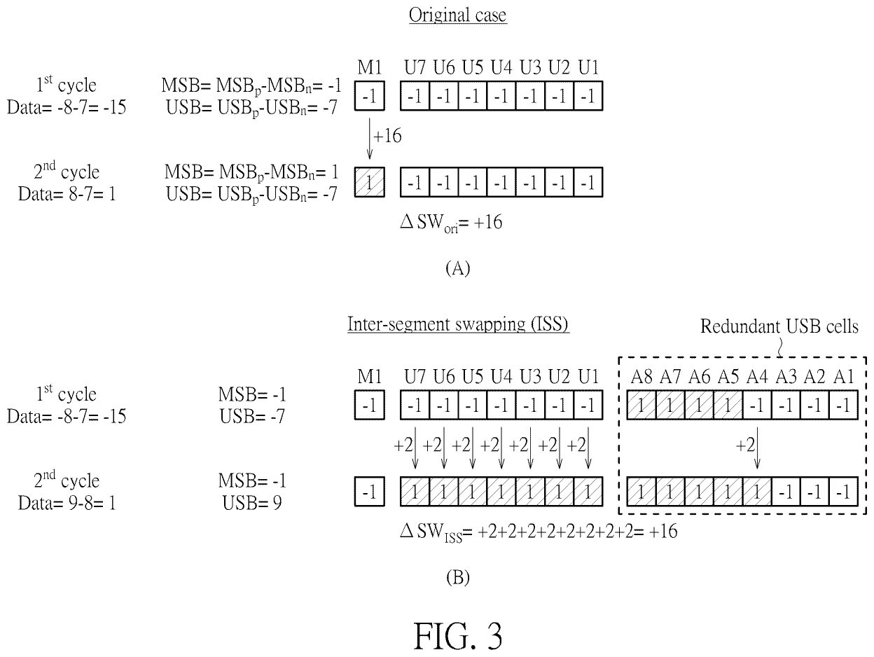

The ISS operation performed at the ISS circuit 104 may include swapping a control bit of one DAC cell included in a higher-significant-bit segment (e.g., MSB segment 106) for control bits of multiple DAC cells included in a lower-significant-bit segment (e.g., USB segment 108). FIG. 3 is a diagram illustrating an ISS operation performed at the ISS circuit 104 according to an embodiment of the present invention. The sub-diagram (A) of FIG. 3 illustrates an original case without using the proposed ISS scheme. During the 1^{st} cycle of the DAC clock, an MSB cell controlled by a control bit M1 is connected to the I_{OUT}− node (denoted by the DAC cell connection state “−1”), and each of the USB cells controlled by control bits U1-U7 is connected to the I_{OUT}− node (denoted by the DAC cell connection state “−1”). Since the current ratio between an MSB cell and a USB cell is 8:1, the differential data represented by an analog output is −15 (i.e., −8−7=−15). During the 2^{nd} cycle of the DAC clock, the MSB cell controlled by the control bit M1 is connected to the I_{OUT}+ node (denoted by the DAC cell connection state “1”), and each of the USB cells controlled by control bits U1-U7 is connected to the I_{OUT}− node (denoted by the DAC cell connection state “−1”). Since the current ratio between an MSB cell and a USB cell is 8:1, the differential data represented by an analog output is 1 (i.e., 8−7=1). The data variation of the original case Δdataₒᵣᵢ is +16.

The sub-diagram (B) of FIG. 3 illustrates an ISS case using the proposed ISS scheme. During the 1^{st} cycle of the DAC clock, the MSB cell controlled by the control bit M1 is connected to the I_{OUT}− node (denoted by the DAC cell connection state “−1”), each of the USB cells controlled by control bits U1-U7 is connected to the I_{OUT}− node (denoted by the DAC cell connection state “−1”), each of the redundant USB cells controlled by control bits A1-A4 is connected to the I_{OUT}− node (denoted by the DAC cell connection state “−1”), and each of the redundant USB cells controlled by control bits A5-A8 is connected to the I_{OUT}+ node (denoted by the DAC cell connection state “1”). Since the current ratio between an MSB cell and a USB cell is 8:1, the differential data represented by an analog output is −15 (i.e., −8−7=−15). During the 2^{nd} cycle of the DAC clock, the MSB cell controlled by the control bit M1 is selected as a swapped MSB cell. Specifically, the ISS operation swaps the control bit M1 of the MSB cell for control bits of multiple USB cells. Compared to the original case that has the MSB cell controlled by the control bit M1 to connect to the I_{OUT}+ node (denoted by the DAC cell connection state “1”), the ISS case changes the control bit M1 from an original value to a new value for connecting the MSB cell to the I_{OUT}− node (denoted by the DAC cell connection state “−1”). As mentioned above, the data variation of the original case Δdataₒᵣᵢ is +16. To ensure that the same differential data is represented by an analog output of the segmented DAC 100, the data variation of the ISS case Δdata_{ISS} is required to be equal to the data variation of the original case Δdataₒᵣᵢ. Hence, the ISS case changes each of the control bits U1-U7 from an original value to a new value for connecting a corresponding USB cell to the I_{OUT}+ node (denoted by the DAC cell connection state “1”), and further changes the control bit A4 from an original value to a new value for connecting a corresponding USB cell (which is a redundant USB cell) to the I_{OUT}+ node (denoted by the DAC cell connection state “1”). In other words, the control bit M1 of one MSB cell is swapped for control bits A4 and U1-U7 of eight USB cells, where a negative-to-positive change of the DAC cell connection state of one MSB cell corresponding to the control bit M1 is replaced by negative-to-positive changes of DAC cell connection states of eight USB cells corresponding to the control bits A4 and U1-U7. Since the current ratio between an MSB cell and a USB cell is 8:1, the differential data represented by an analog output under the ISS case is 1 (i.e., 9−8=1) that is the same as the differential data represented by an analog output under the normal case.

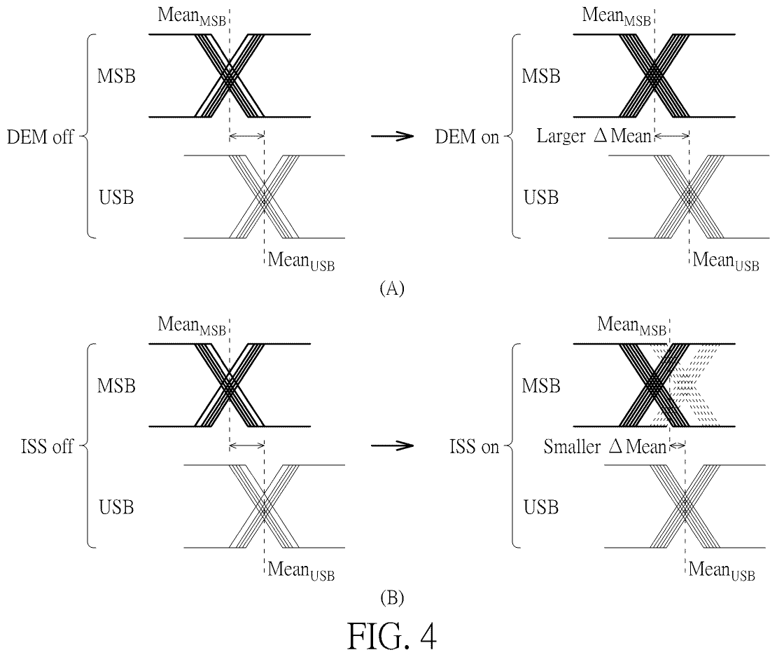

Compared to the conventional DEM technique applied to DAC cells of the same segment, the ISS scheme involves swapping between different segments, and is capable of suppressing distortion induced by timing mismatch between DAC cells of different segments. FIG. 4 is a diagram illustrating a comparison between the conventional DEM technique and the proposed ISS scheme. As shown in sub-diagram (A) of FIG. 4, the conventional DEM technique concentrates the dispersed transition edges in the same segment by randomly selection of the element. Since the random selection is confined within a constrained segment (e.g. among the M1-M15 bits within MSB segment, or among the U1-U7, A1-A8 within USB segment, the difference between mean values of transient edges of the MSB segment and the USB segment is still large, and the conventional DEM technique fails to address the timing mismatch issue between different segments. As shown in sub-diagram (B) of FIG. 4, the proposed ISS scheme concentrates the dispersed transition edges between different segments. Since any MSB may be represented by the combination of USB cells, the difference between mean values of transient edges of the MSB segment and the USB segment is decreased greatly, and the proposed ISS scheme can address the timing mismatch issue between different segments.

Furthermore, compared to the conventional DEM technique, the proposed ISS scheme offers more combinations of DAC cells with equal weighting. Regarding the unary-weighted MSB cells 114_1-114_15, for conventional DEM technique, selecting one MSB cell out of the fifteen possible candidates offers the highest degree of randomization. In contrast, selecting all fifteen MSB cells from the fifteen available options leads to minimal randomization. However, the proposed ISS scheme provides more combinations by swapping one MSB cell to eight USB cells selected from USB cells 116_1-116_7 and 118_1-118_8. Hence, with the aid of the proposed ISS scheme, the segmented DAC 100 with higher linearity can be realized.

To ensure that the same differential data is represented by an analog output of the segmented DAC 100, the data variation of the ISS case Δdata_{ISS} is required to be equal to the data variation of the original case Δdataₒᵣᵢ. Hence, the ISS circuit 104 may require D-type flip-flops (DFFs) and a switching detector to compare a differential data at a previous state (e.g., a differential data during the 1^{st} cycle) and a differential data at a current state (e.g., a differential data during the 2^{nd} cycle), which may have a timing error problem and increase the design complexity. To achieve simpler circuit implementation, the present invention proposes checking bits of the output code 122_2 at the current state to set a post-ISS control code of the USB segment. This approach removes the necessity to check the previous state, thereby eliminating the need of DFFs and switching detectors, and consequently maximizing the operating speed of the ISS circuit. The rules can be derived from following formulas.

$${Δ data}_{ori} = {Δ data}_{ISS} \to {2}^{N} - [ ( {2}^{N} - 1 - K ) - K ] = - {2}^{N} + USB \qquad ( 1 )$$

$$USB = {2}^{N} - [ ( {2}^{N} - 1 - K ) - K ] + {2}^{N} = 1 + {2}^{N} + 2 K \qquad ( 2 )$$

USB is the differential data of all USB cells (which include (2^{N}−1) USB cells), and N is the number of USBs defined in the 14-bit digital input code D_IN.

When a swapped MSB cell is controlled to switch from a positive side (original) to a negative side (ISS), the rule may be expressed as below, where K₁ is the number of bits in the output code 122_2 that are set by values each corresponding to the DAC cell connection state “1”.

$$Original : MSB = 1 ( positive side ) \to ISS : MSB - 1 ( negative side ) \text{} \qquad ( 3 )$$

$$\& Data of all USB cells = ( 1 + {2}^{N} + 2 {K}_{1} )$$

When a swapped MSB cell is controlled to switch from a negative side (original) to a positive side (ISS), the rule may be expressed as below, where K₋₁ is the number of bits in the output code 122_2 that are set by values each corresponding to the DAC cell connection state “−1”.

$$Original : MSB = - 1 ( negative side ) \to ISS : MSB = 1 ( positive side ) \qquad ( 4 )$$

$$\& Data of all USB cells = - ( 1 + {2}^{N} + 2 {K}_{- 1} )$$

In this embodiment, the number of USBs defined in the 14-bit digital input code D_IN is equal to 3 (i.e., N=3). Hence, the above rules can be reformulated as below.

$$Original : MSB = 1 ( positive side ) \to ISS : MSB - 1 ( negative side ) \qquad ( 5 )$$

$$\& Data of all USB cells = ( 1 + {2}^{N} + 2 {K}_{1} ) = 9 + 2 {K}_{1}$$

$$Original : MSB = - 1 ( negative side ) \to ISS : MSB = 1 ( positive side ) \qquad ( 6 )$$

$$\& Data of all USB cells = ( 1 + {2}^{N} + 2 {K}_{- 1} ) = - 9 - 2 {K}_{- 1}$$

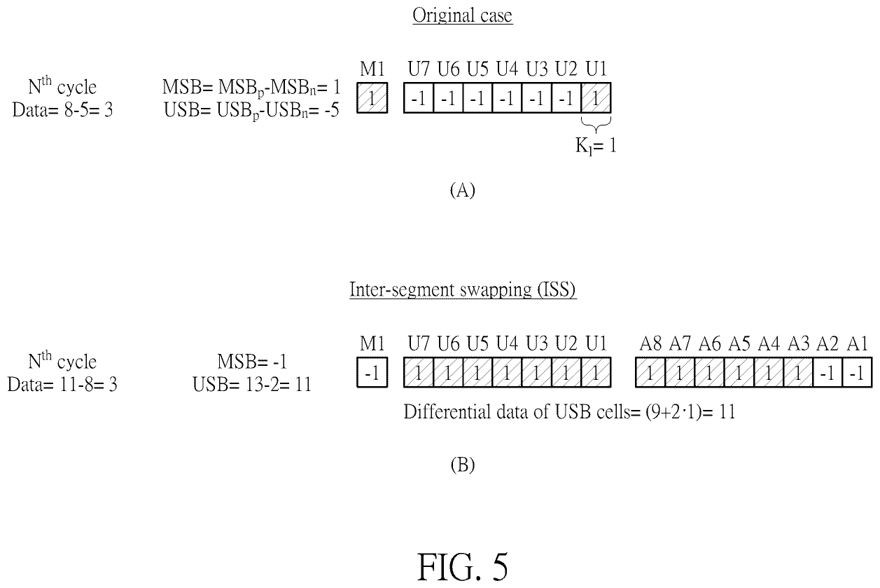

FIG. 5 is a diagram illustrating an ISS operation without checking a previous state according to an embodiment of the present invention. As illustrated in sub-diagram (A) of FIG. 5, a control bit M1 before ISS is set by a value corresponding to the DAC cell connection state “1”, and the number of bits included in the output code 122_2 (which includes 7 control bits U1-U7) that are set by values each corresponding to the DAC cell connection state “1” is equal to 1 (i.e., K₁=1). Hence, the ISS circuit 104 checks the parameter K₁ to know that the differential data represented by the USB segment 108 (which includes 7 USB cells 116_1-116_7 and 8 redundant USB cells 118_1-118_8) should be 11 (i.e., 9+2·1=11). As illustrated in sub-diagram (B) of FIG. 5, the control bit M1 after ISS is set by a new value corresponding to the DAC cell connection state “−1”, the control bits U1-U7 are set by values each corresponding to the DAC cell connection state “1”, the control bits A3-A8 are set by values each corresponding to the DAC cell connection state “1”, and the control bits A1-A2 are set by values each corresponding to the DAC cell connection state “−1”.

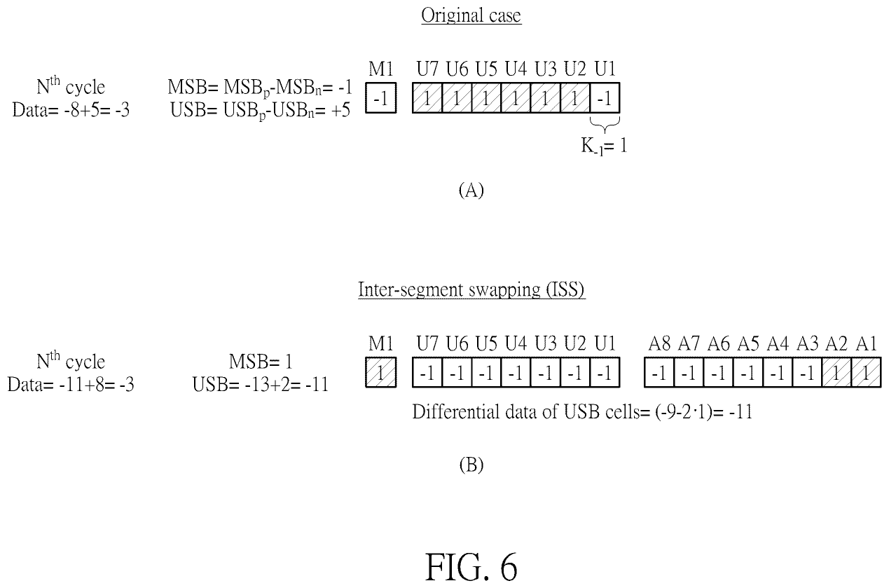

FIG. 6 is a diagram illustrating another ISS operation without checking a previous state according to an embodiment of the present invention. As illustrated in sub-diagram (A) of FIG. 6, a control bit M1 before ISS is set by a value corresponding to the DAC cell connection state “−1”, and the number of bits included in the output code 122_2 (which includes 7 control bits U1-U7) that are set by values each corresponding to the DAC cell connection state “−1” is equal to 1 (i.e., K₋₁=1). Hence, the ISS circuit 104 checks the parameter K₋₁ to know that the differential data represented by the USB segment 108 (which includes 7 USB cells 116_1-116_7 and 8 redundant USB cells 118_1-118_8) should be −11 (i.e., −9−2·1=−11). As illustrated in sub-diagram (B) of FIG. 6, the control bit M1 after ISS is set by a new value corresponding to the DAC cell connection state “1”, the control bits U1-U7 are set by values each corresponding to the DAC cell connection state “−1”, the control bits A3-A8 are set by values each corresponding to the DAC cell connection state “−1”, and the control bits A1-A2 are set by values each corresponding to the DAC connection state “1”.

In some embodiments of the present inventions, the ISS circuit 104 may further receive an ISS enable control signal R_{ISS} and/or an ISS index control signal R_{id}. The ISS enable control signal R_{ISS} is set to control whether to perform/enable an ISS operation. For example, the ISS operation may be enabled when the ISS enable control signal R_{ISS} is set by a pre-defined value (e.g., R_{ISS}=1), and may be disabled when the ISS enable control signal R_{ISS} is set by another pre-defined value (e.g., R_{ISS}=0). A higher frequency of ISS operation enables improved linearity (such as enhanced SFDR performance), but also increases switching activity, potentially reducing SNR performance. By tuning the ISS enable control signal (R_{ISS}), the probability of ISS activation can be adjusted to achieve an optimal balance between linearity and switching activity.

The ISS index control signal Ria is used to carry an index value for selecting a swapped MSB cell from the MSB segment 106. Specifically, the ISS operation is performed upon a control bit of a swapped MSB cell that is located at a position indexed by the index value carried by the ISS index control signal R_{id}. The index value may be a fixed value or a random value. In cases where the index value is fixed, the ISS index control signal R_{id} carries the same index value at each time instant. As a result, the swapped MSB cells selected at different times are identical, adhering to a fixed sequence. In contrast, when the index value is randomly varied, the ISS index control signal Ria provides different index values at different time instants. Consequently, the swapped MSB cells are randomly selected at each time instant, resulting in a random sequence. For example, the random sequence carried by the ISS index control signal R_{id} may be set by a pseudo random (PN) sequence generator or a dither generator.

In this embodiment, the 14-bit digital input code D_IN includes 3 USBs, and the USB segment 108 includes (2³−1) DAC cells (i.e., USB cells) 116_1-116_7 and 8 (M=8) redundant DAC cells (i.e., redundant USB cells) 118_1-118_8. Hence, the total number of USB cells included in the USB segment 108 is 15 (i.e., 7+8=15). However, the number of redundant USB cells may be adjusted depending upon actual design considerations. Specifically, the number of redundant USB cells is set based on tradeoff between hardware cost and output linearity. In addition, the number of redundant USB cells may also control whether an ISS operation can be enabled. In this embodiment, the total number of USB cells is 15 (i.e., 7+8=15). Hence, the maximum differential data that can be represented by the analog output A_2 of the USB segment 108 is +15, and the minimum differential data that can be represented by the analog output A_2 of the USB segment 108 is −15. Regarding the differential data USB of all USB cells (which include (2^{N}−1) USB cells and M redundant USB cells) in above formula (3), it should meet the following criterion.

$$USB = 9 + 2 {K}_{1} \leq 7 + 8 = 15 \to {K}_{1} \leq \frac{[ ( 7 + 8 ) - 9 ]}{2} = 3 \qquad ( 7 )$$

Regarding the differential data USB of all USB cells (which include (2^{N}−1) USB cells and M redundant USB cells) in above formula (4), it should meet the following criterion.

$$USB = 9 + 2 {K}_{- 1} \leq 7 + 8 = 15 \to {K}_{- 1} \leq \frac{[ ( 7 + 8 ) - 9 ]}{2} = 3 \qquad ( 8 )$$

In some embodiments of the present invention, the ISS enable control signal R_{ISS} is absent, and the parameter K₁/K₋₁ may be considered to determine whether to perform/enable the ISS operation. In some embodiments of the present invention, the ISS enable control signal R_{ISS} is present, and the ISS enable control signal R_{ISS} and the parameter K₁/K₋₁ may be jointly considered to determine whether to perform/enable the ISS operation.

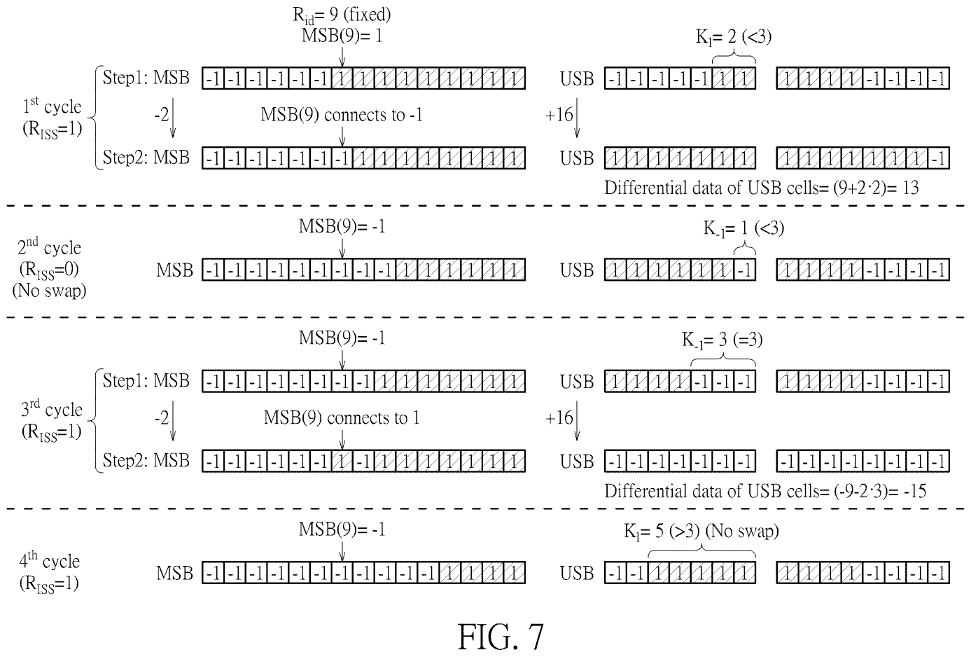

FIG. 7 is a diagram illustrating an ISS operation controlled by a fixed sequence carried by the ISS index control signal R_{id} according to an embodiment of the present invention. In this embodiment, the ISS index control signal R_{id} is configured to carry a fixed value (e.g., R_{id}=9). During the 1^{st} cycle of the DAC clock, the ISS enable control signal R_{ISS} is set by a pre-defined value (e.g., R_{ISS}=1) and the parameter K₁ is not larger than a pre-defined threshold (e.g., 3). Hence, the ISS operation is enabled to swap a control bit of a swapped MSB cell MSB(9) located at a position indexed by R_{id}=9 for control bits of multiple USB cells, where the differential data of all USB cells in the USB segment 108 is 13 (i.e., 9+2·2=13) that is determined without checking a previous state.

During the 2^{nd} cycle of the DAC clock, the ISS enable control signal R_{ISS} is set by another pre-defined value (e.g., R_{ISS}=0) and the parameter K₋₁ is not larger than the pre-defined threshold (e.g., 3). The ISS operation is disabled due to R_{ISS}=0.

During the 3^{rd} cycle of the DAC clock, the ISS enable control signal R_{ISS} is set by the pre-defined value (e.g., R_{ISS}=1) and the parameter K₋₁ is not larger than the pre-defined threshold (e.g., 3). Hence, the ISS operation is enabled to swap a control bit of a swapped MSB cell MSB(9) located at a position indexed by R_{id}=9 for control bits of multiple USB cells, where the differential data of all USB cells in the USB segment 108 is −15 (i.e., −9−2·3=−15) that is determined without checking a previous state.

During the 4^{th} cycle of the DAC clock, the ISS enable control signal R_{ISS} is set by the pre-defined value (e.g., R_{ISS}=1) and the parameter K₁ is larger than the pre-defined threshold (e.g., 3). The ISS operation is disabled due to K₁>3.

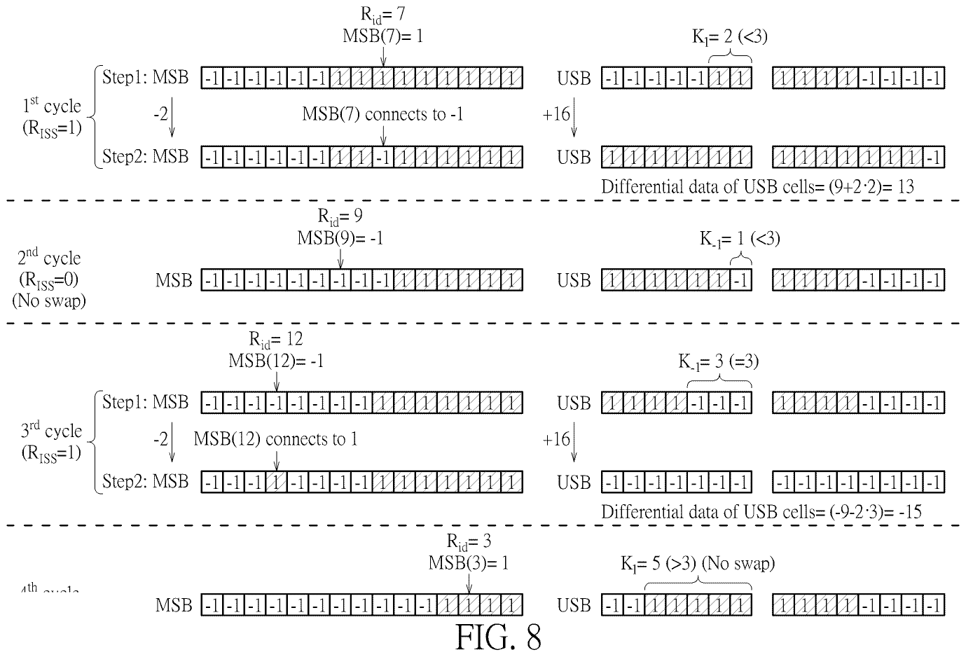

FIG. 8 is a diagram illustrating an ISS operation controlled by a random sequence carried by the ISS index control signal R_{id} according to an embodiment of the present invention. In this embodiment, the ISS index control signal R_{id} transmits a random sequence of values (e.g., 7, 9, 12, and 3). During the 1^{st} cycle of the DAC clock, the ISS enable control signal R_{ISS} is set by a pre-defined value (e.g., R_{ISS}=1) and the parameter K₁ is not larger than a pre-defined threshold (e.g., 3). Hence, the ISS operation is enabled to swap a control bit of a swapped MSB cell MSB(7) located at a position indexed by R_{id}=7 for control bits of multiple USB cells, where the differential data of all USB cells in the USB segment 108 is 13 (i.e., 9+2.2=13) that is determined without checking a previous state.

During the 2^{nd} cycle of the DAC clock, the ISS enable control signal R_{ISS} is set by another pre-defined value (e.g., R_{ISS}=0) and the parameter K₋₁ is not larger than the pre-defined threshold (e.g., 3). The ISS operation is disabled due to R_{ISS}=0.

During the 3^{rd} cycle of the DAC clock, the ISS enable control signal R_{ISS} is set by the pre-defined value (e.g., R_{ISS}=1) and the parameter K₋₁ than the pre-defined threshold (e.g., 3). Hence, the ISS operation is enabled to swap a control bit of a swapped MSB cell MSB(12) located at a position indexed by R_{id}=12 for control bits of multiple USB cells, where the differential data of all USB cells in the USB segment 108 is −15 (i.e., −9−2.3=−15) that is determined without checking a previous state.

During the 4^{th} cycle of the DAC clock, the ISS enable control signal R_{ISS} is set by the pre-defined value (e.g., R_{ISS}=1) and the parameter K₁ is larger than the pre-defined threshold (e.g., 3). The ISS operation is disabled due to K₁>3.

In some embodiments of the present invention, the proposed ISS scheme may collaborate with the conventional DEM technique to achieve better linearity performance. In this arrangement, the proposed ISS scheme addresses the mismatch effect between different segments, while the DEM technique mitigates the mismatch effect among DAC cells within the same segment. For example, a layout design of the segmented DAC 100 may place MSB cells 114_1-114_15 close to each other, while some of USB cells 116_1-116_7 and 118_1-118_8 may be placed on one side of the MSB segment 106 and the rest of USB cells 116_1-116_7 and 118_1-118_8 on the other side of the MSB segment 106. In other words, the layout positions of some USB cells are not adjacent to those of the remaining USB cells. Therefore, the DEM technique is applied to the control bits of the USB cells rather than the control bits of the MSB cells.

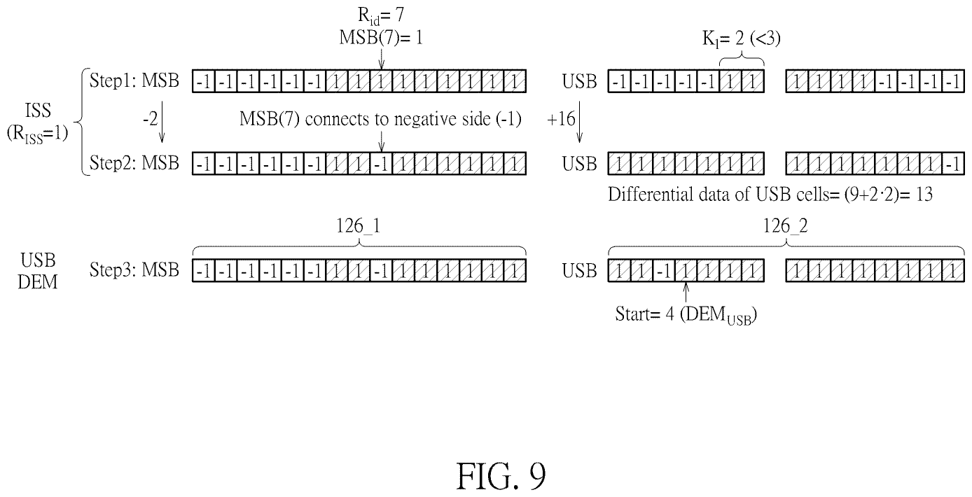

FIG. 9 is a diagram illustrating an ISS operation with USB DEM according to an embodiment of the present invention. During one cycle of the DAC clock, the ISS enable control signal R_{ISS} is set by a pre-defined value (e.g., R_{ISS}=1) and the parameter K₁ is not larger than a pre-defined threshold (e.g., 3). Hence, the ISS operation is enabled to swap a control bit of a swapped MSB cell MSB(7) located at a position indexed by R_{id}=7 for control bits of multiple USB cells, where the differential data of all USB cells in the USB segment 108 is 13 (i.e., 9+2.2=13) that is determined without checking a previous state. In this embodiment, the ISS operation generates a post-ISS control code 126_1 for the MSB segment 106 and a post-ISS control code 126_2 for the USB segment 108, and then processes the post-ISS control code 126_2 for the USB segment 108 according to a DEM algorithm. As shown in FIG. 9, the control bits of the post-ISS control code 126_2 are shuffled according to a start position randomly selected by a random signal DEM_{USB}.

It should be noted that the present invention has no limitations on the DEM algorithm that collaborates with the proposed ISS scheme. Furthermore, the post-ISS control code 126_1 for the MSB segment 106 is not processed by any DEM algorithm. In this embodiment, the current ratio between an MSB cell and a USB cell is 8:1. Using a DEM technique to randomize control bits of the MSB segment induces substantial switching activity. Hence, shuffling of MSB control bits is restricted to minimize the switching activity. The segmented DAC design proposed herein, which incorporates ISS and USB DEM, demonstrates lower switching activity within a single DAC clock cycle compared to conventional segmented DAC design employing both MSB DEM and USB DEM. Thus, the proposed ISS scheme reduces mismatch distortion while incurring less switching activity than conventional DEM techniques.

Regarding the embodiment shown in FIG. 1, the ISS circuit 104 is configured to perform swapping between an MSB segment and a USB segment. However, this is for illustrative purposes only, and is not meant to be a limitation of the present invention. In practice, the proposed ISS scheme can be applied to any segments, including a higher-significant-bit segment and a lower-significant-bit segment, for swapping a control bit of a DAC cell included in the higher-significant-bit segment for control bits of multiple DAC cells included in the lower-significant-bit segment. For example, the ISS circuit 104 may be modified to perform swapping between a USB segment and an LSB segment. This alternative design also falls within the scope of the present invention.

Regarding the embodiment shown in FIG. 1, the ISS circuit 104 is configured to swap a control bit of a DAC cell included in a higher-significant-bit segment for control bits of multiple DAC cells included in a lower-significant-bit segment. However, this is for illustrative purposes only, and is not meant to be a limitation of the present invention. The inter-segment swapping concept can be extended to particular cases, including one case of swapping a control bit of one DAC cell included in a higher-significant-bit segment for control bits of all DAC cells included in one or more lower-significant-bit segments and another case of swapping control bits of all DAC cells included in one or more lower-significant-bit segments for a control bit of one DAC cell included in a higher-significant-bit segment.

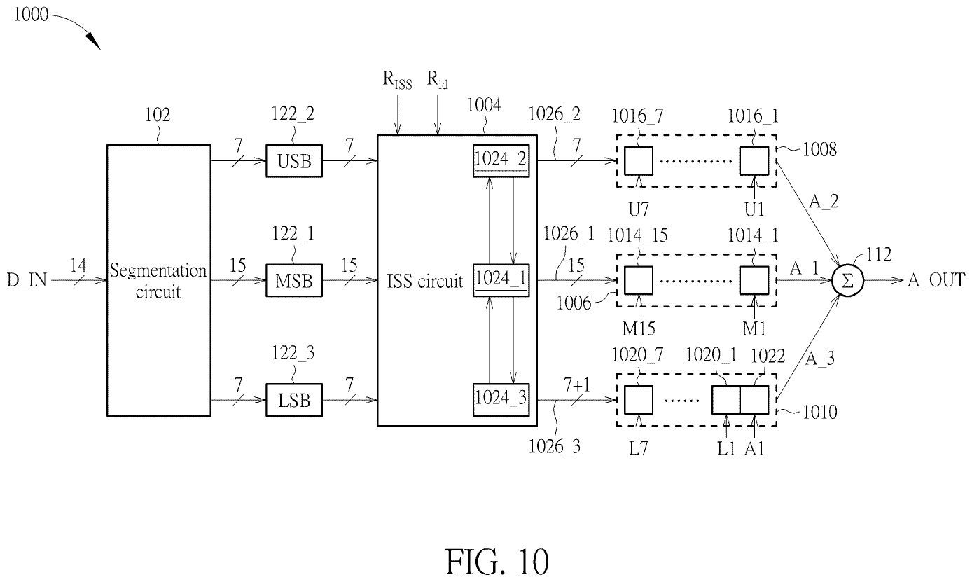

FIG. 10 is a diagram illustrating another segmented DAC with ISS according to an embodiment of the present invention. The segmented DAC 1000 includes an ISS circuit 1004, a plurality of segments 1006, 1008, 1010, and aforementioned segmentation circuit 102 and combining circuit 112. Like the segmented DAC 100, the segmented DAC 1000 is used to receive a 14-bit digital input code D_IN, and perform digital-to-analog conversion upon the 14-bit digital input code D_IN to generate an analog output A_OUT. In a case where the segmented DAC 1000 is a current-steering DAC, the analog output A_OUT may be an analog current output. For example, the analog current output may be a differential pair consisting of I_{OUT}+ and I_{OUT}−.

The segment 1006 is an MSB segment including DAC cells (i.e., MSB cells) 1014_1-1014_15. The segment 1008 is a USB segment including DAC cells (i.e., USB cells) 1016_1-1016_7. The segment 1010 is an LSB segment including DAC cells (i.e., LSB cells) 1020_1-1020_7 and 1022. The LSB cell 1022 is a redundant LSB cell required by the proposed ISS scheme. The ISS circuit 1004 is configured to derive a pre-ISS control code 1024_1 of the MSB segment (i.e., a higher-significant-bit segment) 1006 from the output code 122_1, a pre-ISS control code 1024_2 of the USB segment (i.e., one lower-significant-bit segment) 1008 from the output code 122_2, and a pre-ISS control code 1024_3 of the LSB segment (i.e., another lower-significant-bit segment) 1010 from the output code 122_3. The pre-ISS control code 1024_1 includes 15 control bits {M1, . . . , M15} corresponding to MSB cells 1014_1-1014_15 of the MSB segment 1006, respectively. The pre-ISS control code 1024_2 includes 7 control bits {U1, . . . , U7} corresponding to USB cells 1016_1-1016_7 of the USB segment 1008, respectively. The pre-ISS control code 1024_3 includes (7+1) control bits {L1, . . . , L7, A1} corresponding to LSB cells 1020_1-1020_7 and 1022 of the LSB segment 1010, respectively.

The ISS circuit 1004 is further configured to perform an ISS operation upon the pre-ISS control codes 1024_1-1024_3 to generate a post-ISS control code 1026_1 of the MSB segment 1006, a post-ISS control code 1026_2 of the USB segment 1008, and a post-ISS control code 1026_3 of the LSB segment 1010. The post-ISS control code 1026_1 includes 15 control bits {M1, . . . , M15} corresponding to MSB cells 1014_1-1014_15 of the MSB segment 1006, respectively, and has one control bit with a value different from a value of the same control bit included in the pre-ISS control code 1024_1 due to the ISS operation. The post-ISS control code 1026_2 includes 7 control bits {U1, . . . , U7} corresponding to USB cells 1016_1-1016_7 of the USB segment 1008, respectively, and has all control bits with values different from values of the same control bits included in the pre-ISS control code 1024_2 due to the ISS operation. The post-ISS control code 1026_3 includes (7+1) control bits {L1, . . . , L7, A1} corresponding to LSB cells 1020_1-1020_7 and 1022 of the LSB segment 1010, respectively, and has all control bits with values different from values of the same control bits included in the pre-ISS control code 1024_3 due to the ISS operation.

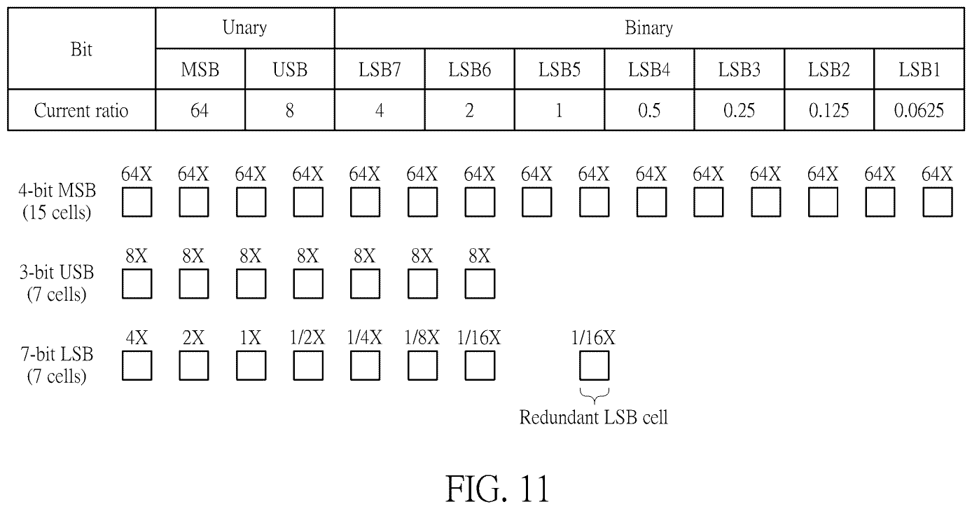

For better comprehension of technical features of the proposed ISS scheme, the following assumes that each of the MSB segment 1006, the USB segment 1008, and the LSB segment 1010 may be a current-steering DAC. Each of the DAC cells 1014_1-1014_15, 1016_1-1016_7, 1020_1-1020_7, 1022 may include a current source and a switch element, where the switch element is controlled by a control bit to steer a current of the current source to an I_{OUT}+ node or an I_{OUT}− node. FIG. 11 is a diagram illustrating current ratio settings of the DAC cells 1014_1-1014_15, 1016_1-1016_7, 1020_1-1020_7, 1022 shown in FIG. 10. Regarding the MSB segment 1006, the MSB cells 1014_1-1014_15 are unary-weighted DAC cells each having a current ratio of 64X. Regarding the USB segment 1008, the USB cells 1016_1-1016_7 are unary-weighted DAC cells each having a current ratio of 8X. Regarding the LSB segment 1010, the LSB cells (e.g., LSB1-LSB7) 1020_1-1020_7 are binary-weighted DAC cells having current ratios of (1/16)X, (1/8)X, (1/4)X, (1/2)X, 1X, 2X, 4X, respectively, and the DAC cell 1022 is a redundant LSB cell (e.g., redundantLSB1) having a current ratio of (1/16)X that is the same as that of the DAC cell (e.g., LSB1) 1020_1.

When a control bit is set by a first value, a switch element is controlled to steer the current of the current source to the I_{OUT}+ node, resulting in one DAC cell connection state “1”; and when the control bit is set by a second value, the switch element is controlled to steer the current of the current source to the I_{OUT}− node, resulting in another DAC cell connection state “−1”. The combining circuit 112 is configured to combine an analog output A_1 (e.g., analog current outputs I_{OUT}+, I_{OUT}−) of the MSB segment 1006, an analog output A_2 (e.g., analog current outputs I_{OUT}+, I_{OUT}−) of the USB 1008, and an analog output A_3 (e.g., analog current outputs I_{OUT}+, I_{OUT}−) of the LSB segment 1010 to generate the analog output A_OUT (e.g., analog current outputs I_{OUT}+, I_{OUT}−) of the segmented DAC 1000.

The ISS operation performed at the ISS circuit 1004 may include swapping a control bit of one DAC cell included in a higher-significant-bit segment (e.g., MSB segment 1006) for control bits of all DAC cells included in one or more lower-significant-bit segments (e.g., USB segment 1008 and LSB segment 1010), or swapping control bits of all DAC cells included in one or more lower-significant-bit segments (e.g., USB segment 1008 and LSB segment 1010) for a control bit of one DAC cell included in a higher-significant-bit segment (e.g., MSB segment 1006).

FIG. 12 is a diagram illustrating an ISS operation performed at the ISS circuit 1004 according to an embodiment of the present invention. The pre-ISS control code 1024_1 may include one control bit (e.g., M1) set by a value corresponding to the DAC cell connection state “−1”. The pre-ISS control code 1024_2 may include all control bits {U7, . . . , U1} set by values each corresponding to the DAC cell connection state “1”. The pre-ISS control code 1024_3 may include all control bits {L7, . . . , L1} set by values each corresponding to the DAC cell connection state “1”, and {A1} set to a tri-state ‘0’ signifying that its current is disabled and does not flow to either I_{OUT}+ or I_{OUT}−. After the ISS operation is performed upon the pre-ISS control codes 1024_1-1024_3, the post-ISS control code 1026_1 may include one control bit (e.g., M1) set by a new value corresponding to the DAC cell connection state “1”, the post-ISS control code 1026_2 may include all control bits {U7, . . . , U1} set by new values each corresponding to the DAC cell connection state “−1”, and the post-ISS control code 1026_3 may include all control bits {L7, . . . , L1, A1} set by new values each corresponding to the DAC cell connection state “−1”.

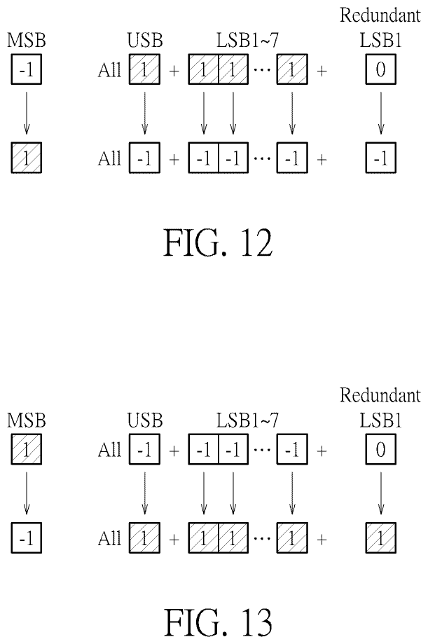

FIG. 13 is a diagram illustrating another ISS operation performed at the ISS circuit 1004 according to an embodiment of the present invention. The pre-ISS control code 1024_1 may include one control bit (e.g., M1) set by a value corresponding to the DAC cell connection state “1”. The pre-ISS control code 1024_2 may include all control bits {U7, . . . , U1} set by values each corresponding to the DAC cell connection state “−1”. The pre-ISS control code 1024_3 may include all control bits {L7, . . . , L1} set by values each corresponding to the DAC cell connection state “−1”, and {A1} set to a tri-state ‘0’ signifying that its current is disabled and does not flow to either I_{OUT}+ or I_{OUT}−. After the ISS operation is performed upon the pre-ISS control codes 1024_1-1024_3, the post-ISS control code 1026_1 may include one control bit (e.g., M1) set by a new value corresponding to the DAC cell connection state “−1”, the post-ISS control code 1026_2 may include all control bits {U7, . . . , U1} set by new values each corresponding to the DAC cell connection state “1”, and the post-ISS control code 1026_3 may include all control bits {L7, . . . , L1, A1} set by new values each corresponding to the DAC cell connection state “1”.

In summary, the segmented DAC with ISS can significantly suppress distortion induced by amplitude and timing mismatch between different DAC segments, resulting in improved linearity. Compared to the conventional DEM technique (MSB DEM & USB DEM), the proposed ISS scheme reduces switching activity, thereby conserving more noise spectral density (NSD) budget. Furthermore, the effectiveness of the segmented DAC with ISS is not limited by specific digital backoffs, enhancing its robustness. To put it simply, the segmented DAC with ISS provides superior linearity, lower noise overhead, and greater robustness compared to conventional segmented DACs.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An inter-segment swapping (ISS) method for controlling a plurality of segments of a segmented digital-to-analog converter (DAC), comprising:
receiving a first output code derived from higher significant bits of a digital input code of the segmented DAC;
receiving a second output code derived from lower significant bits of the digital input code of the segmented DAC;
deriving a first pre-ISS control code of a higher-significant-bit segment included in the plurality of segments of the segmented DAC from the first output code, wherein the first pre-ISS control code comprises first control bits corresponding to first DAC cells of the higher-significant-bit segment, respectively;
deriving a second pre-ISS control code of a lower-significant-bit segment included in the plurality of segments of the segmented DAC from the second output code, wherein the second pre-ISS control code comprises second control bits corresponding to second DAC cells of the lower-significant-bit segment, respectively; and
performing an ISS operation upon the first pre-ISS control code and the second pre-ISS control code to generate a first post-ISS control code of the higher-significant-bit segment and a second post-ISS control code of the lower-significant-bit segment, comprising:
swapping a first control bit of a first DAC cell included in the higher-significant-bit segment for second control bits of multiple second DAC cells included in the lower-significant-bit segment.

2. The ISS method of claim 1, wherein the higher-significant-bit segment is a most significant bit (MSB) segment.

3. The ISS method of claim 1, wherein swapping the first control bit of the first DAC cell included in the higher-significant-bit segment for the second control bits of the multiple second DAC cells included in the lower-significant-bit segment comprises:
generating the first post-ISS control code of the higher-significant-bit segment by changing the first control bit of the first DAC cell from a first value to a second value, wherein the first value corresponds to a first DAC cell connection state, and the second value corresponds to a second DAC cell connection state; and
generating the second post-ISS control code of the lower-significant-bit segment by checking a number of bits in the second output code that are set by values each corresponding to the first DAC cell connection state.

4. The ISS method of claim 3, wherein generating the second post-ISS control code of the lower-significant-bit segment by checking the number of bits in the second output code that are set by values each corresponding to the first DAC cell connection state comprises:
checking if the number of bits is not larger than a pre-defined threshold; and
in response to the number of bits being not larger than the pre-defined threshold, generating the second post-ISS control code of the lower-significant-bit segment according to the number of bits.

5. The ISS method of claim 1, wherein the second pre-ISS control code comprises a first code segment and a second code segment, the first code segment is set by the second output code, and the second DAC cells of the lower-significant-bit segment comprise redundant DAC cells corresponding to the second code segment.

6. The ISS method of claim 5, wherein the second DAC cells of the lower-significant-bit segment are unary-weighted DAC cells of a same architecture.

7. The ISS method of claim 1, wherein performing the ISS operation upon the first pre-ISS control code and the second pre-ISS control code to generate the first post-ISS control code of the higher-significant-bit segment and the second post-ISS control code of the lower-significant-bit segment further comprises:
checking an ISS enable signal which controls whether to perform the ISS operation; and
in response to the ISS enable signal set by a pre-defined value, performing the ISS operation upon the first pre-ISS control code and the second pre-ISS control code.

8. The ISS method of claim 7, wherein the ISS enable signal is tunable.

9. The ISS method of claim 1, wherein performing the ISS operation upon the first pre-ISS control code and the second pre-ISS control code to generate the first post-ISS control code of the higher-significant-bit segment and the second post-ISS control code of the lower-significant-bit segment further comprises:
selecting the first control bit of the first DAC cell that is located at a position indexed by an index value carried by an ISS index control signal.

10. The ISS method of claim 9, wherein the index value is a fixed value or a random value.

11. The ISS method of claim 1, further comprising:
processing the second post-ISS control code of the lower-significant-bit segment according to a dynamic element matching (DEM) algorithm.

12. An inter-segment swapping (ISS) method for controlling a plurality of segments of a segmented digital-to-analog converter (DAC), comprising:
receiving a first output code derived from higher significant bits of a digital input code of the segmented DAC;
receiving one or more second output codes derived from lower significant bits of the digital input code of the segmented DAC;
deriving a first pre-ISS control code of a higher-significant-bit segment included in the plurality of segments of the segmented DAC from the first output code, wherein the first pre-ISS control code comprises first control bits corresponding to first DAC cells of the higher-significant-bit segment, respectively;
deriving one or more second pre-ISS control codes of one or more lower-significant-bit segments included in the plurality of segments of the segmented DAC from the one or more second output codes, wherein the one or more second pre-ISS control codes comprise second control bits corresponding to second DAC cells of the one or more lower-significant-bit segments, respectively; and
performing an ISS operation upon the first pre-ISS control code and the one or more second pre-ISS control codes to generate a first post-ISS control code of the higher-significant-bit segment and one or more second post-ISS control codes of the one or more lower-significant-bit segments, comprising:
swapping a first control bit of a first DAC cell included in the higher-significant-bit segment for second control bits of all second DAC cells included in the one or more lower-significant-bit segments; or
swapping second control bits of all second DAC cells included in the one or r lower-significant-bit segments for a first control bit of a first DAC cell included in the higher-significant-bit segment.

13. The ISS method of claim 12, wherein the higher-significant-bit segment is a most significant bit (MSB) segment.

14. A segmented digital-to-analog converter (DAC) comprising:
a plurality of segments, comprising:
a higher-significant-bit segment, having first DAC cells; and
a lower-significant-bit segment, having second DAC cells;
a combining circuit, configured to combine a plurality of analog outputs of the plurality of segments;
a segmentation circuit, configured to derive a first output code from higher significant bits of a digital input code of the segmented DAC, and derive a second output code from lower significant bits of the digital input code of the segmented DAC; and
an inter-segment swapping (ISS) circuit, configured to derive a first pre-ISS control code of the higher-significant-bit segment from the first output code, derive a second pre-ISS control code of the lower-significant-bit segment from the second output code, and perform an ISS operation upon the first pre-ISS control code and the second pre-ISS control code to generate a first post-ISS control code of the higher-significant-bit segment and a second post-ISS control code of the lower-significant-bit segment, wherein the first pre-ISS control code comprises first control bits corresponding to the first DAC cells, respectively, the second pre-ISS control code comprises second control bits corresponding to the second DAC cells, respectively, and the ISS operation comprises swapping a first control bit of a first DAC cell included in the higher-significant-bit segment for second control bits of multiple included in the lower-second DAC cells significant-bit segment.

15. The segmented DAC of claim 14, wherein the higher-significant-bit segment is a most significant bit (MSB) segment.

16. The segmented DAC of claim 14, wherein the ISS circuit is configured to generate the first post-ISS control code of the higher-significant-bit segment by changing the first control bit of the first DAC cell from a first value to a second value, where the first value corresponds to a first DAC cell connection state, and the second value corresponds to a second DAC cell connection state; and the ISS circuit is further configured to generate the second post-ISS control code of the lower-significant-bit segment by checking a number of bits in the second output code that are set by values each corresponding to the first DAC cell connection state.

17. The segmented DAC of claim 14, wherein the second pre-ISS control code comprises a first code segment and a second code segment, the first code segment is set by the second output code, and the second DAC cells of the lower-significant-bit segment comprise redundant DAC cells corresponding to the second code segment.

18. The segmented DAC of claim 14, wherein the ISS circuit is further configured to check an ISS enable signal which controls whether to perform the ISS operation; and the ISS circuit performs the ISS operation upon the first pre-ISS control code and the second pre-ISS control code when the ISS enable signal is set by a pre-defined value.

19. The segmented DAC of claim 14, wherein the ISS circuit is configured to select the first control bit of the first DAC cell that is located at a position indexed by an index value carried by an ISS index control signal.

20. The segmented DAC of claim 14, wherein the ISS circuit is further configured to process the second post-ISS control code of the lower-significant-bit segment according to a dynamic element matching (DEM) algorithm.
